(19) United States
(12) Patent Application Publication
(10) Pub. No.: US 2025/0273501 A1
(43) Pub. Date: Aug. 28, 2025

(54) TEMPORARY PROTECTION FILM FOR PRODUCTION OF SEMICONDUCTOR DEVICE AND PRODUCTION METHOD FOR SEMICONDUCTOR DEVICE

(71) Applicant: Resonac Corporation, Minato-ku, Tokyo (JP)

(72) Inventor: Kodai ITO, Minato-ku, Tokyo (JP)

(21) Appl. No.: 18/857,812

(22) PCT Filed: May 12, 2023
(86) PCT No.: PCT/JP2023/017970

§ 371 Date: Oct. 18, 2024

(30) Foreign Application Priority Data
Jun. 3, 2022 (JP) 2022-090987

(51) Int. Cl. H01L 21/683; C09J 7/30; C09J 11/06; C09J 133/10; H01L 21/56

(52) U.S. Cl. CPC H01L 21/6835; C09J 7/30; C09J 11/06; C09J 133/10; H01L 21/566; H01L 21/568; C09J 2203/326; C09J 2301/408; C09J 2301/414; C09J 2301/502; H01L 2221/68386

(57) ABSTRACT

A temporary protective film for production of a semiconductor device, containing a support film and an adhesive layer provided on the support film, wherein the adhesive layer contains a polymer containing an alkyl (meth)acrylate, (meth)acryloylmorpholine, and a monomer having a crosslinking group, as monomer units and a crosslinking agent capable of crosslinking with the crosslinking group, and wherein a content of the (meth)acryloylmorpholine is 7% by mass or more based on a total amount of the monomer units of the polymer.

### TECHNICAL FIELD

The present disclosure relates to a temporary protective film for production of a semiconductor device and a production method for a semiconductor device.

### BACKGROUND ART

In semiconductor packages, a structure is sometimes adopted in which an encapsulating layer is formed only on the semiconductor element side of the lead frame, and the back surface of the lead frame is exposed. In the production of a semiconductor package having this structure, there is a risk that the encapsulant may spread to the back surface of the lead frame when the encapsulating layer is formed. In order to prevent this, a method is known in which a temporary protective film is attached to the back surface of the lead frame (Patent Literature 1). The temporary protective film is peeled off from the lead frame after the encapsulating layer is formed.

### CITATION LIST

### Patent Literature

Patent Literature 1: International Publication WO 2001/035460

### SUMMARY OF INVENTION

### Technical Problem

It is desirable that a temporary protective film has excellent adhesive strength so as to be attached to an adherend such as a lead frame at room temperature (for example, 25° C.) as well as adhesive components of the temporary protective film do not remain on the adherend when the temporary protective film is peeled off from the adherend. However, it is not necessarily easy to achieve both of these.

Accordingly, an object of an aspect of the present invention is to provide a temporary protective film that has excellent adhesive strength at room temperature and can be prevented from remaining on an adherend when peeled off.

### Solution to Problem

The present inventors have studied to use a polymer containing an alkyl (meth)acrylate, (meth)acryloylmorpholine, and a monomer having a crosslinking group as monomer units in the adhesive layer of a temporary protective film. As a result, it has been demonstrated that it is possible to achieve both excellent adhesive strength at room temperature and suppression of the occurrence of remaining on an adherend when the content of (meth)acryloylmorpholine is equal to or greater than a specific amount.

The present invention includes the following aspects.

[1] A temporary protective film for production of a semiconductor device, including a support film and an adhesive layer provided on the support film, wherein the adhesive layer contains a polymer containing an alkyl (meth)acrylate, (meth)acryloylmorpholine, and a monomer having a crosslinking group, as monomer units and a crosslinking agent capable of crosslinking with the crosslinking group, and a content of the (meth)acryloylmorpholine is 7% by mass or more based on a total amount of monomer units of the polymer.

[2] The temporary protective film according to [1], wherein the crosslinking group is an acidic group and the crosslinking agent has an epoxy group.

[3] The temporary protective film according to [2], wherein the crosslinking agent further has an amino group.

[4] The temporary protective film according to any one of [1] to [3], wherein the crosslinking agent has a group represented by the following Formula (1):

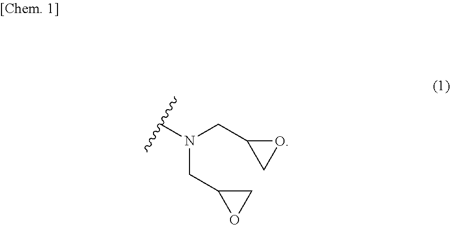 [SMILES: *N(CC1CO1)CC1CO1]

[5] A method for producing a semiconductor device, including: attaching a temporary protective film to one surface side of a substrate; mounting a semiconductor element on a surface of the substrate opposite to the temporary protective film; encapsulating the semiconductor element; and peeling off the temporary protective film from the substrate, in this order, wherein the temporary protective film contains a support film and an adhesive layer provided on the support film, the adhesive layer contains a polymer containing an alkyl (meth)acrylate, (meth)acryloylmorpholine, and a monomer having a crosslinking group, as monomer units and a crosslinking agent capable of crosslinking with the crosslinking group, and a content of the (meth)acryloylmorpholine is 7% by mass or more based on a total amount of the monomer units of the polymer.

[6] The method according to [5], wherein the crosslinking group is an acidic group and the crosslinking agent has an epoxy group.

[7] The method according to [6], wherein the crosslinking agent further has an amino group.

[8] The method according to any one of [5] to [7], wherein the crosslinking agent has a group represented by the following Formula (1):

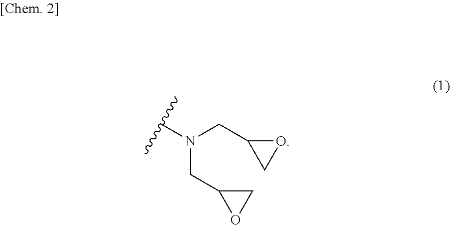 [SMILES: *N(CC1CO1)CC1CO1]

### Advantageous Effects of Invention

According to an aspect of the present invention, it is possible to provide a temporary protective film that has excellent adhesive strength at room temperature and can be prevented from remaining on an adherend when peeled off.

### BRIEF DESCRIPTION OF DRAWINGS

FIG. 1 is a cross-sectional view illustrating an embodiment of a temporary protective film.

FIG. 2 is a cross-sectional view for explaining an embodiment of a production method for a semiconductor device.

FIG. 3 is a cross-sectional view for explaining an embodiment of a production method for a semiconductor device.

FIG. 4 is a cross-sectional view illustrating an embodiment of a semiconductor device.

FIG. 5 is a perspective view illustrating an embodiment of a reel body.

### DESCRIPTION OF EMBODIMENTS

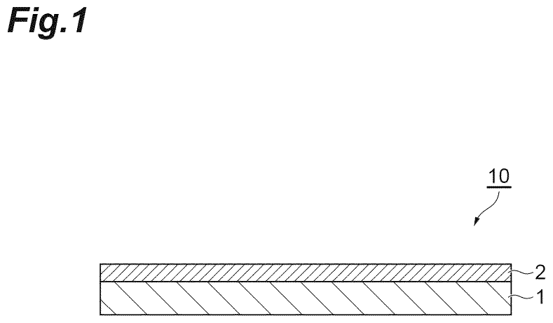

Hereinafter, an embodiment of the present invention will be described. FIG. 1 is a cross-sectional view illustrating a temporary protective film according to an embodiment. As illustrated in FIG. 1, a temporary protective film 10 according to an embodiment contains a support film 1 and an adhesive layer 2 provided on the support film 1. The temporary protective film 10 can be used as a temporary protective film for production of a semiconductor device. More specifically, the temporary protective film 10 can be used as a temporary protective film for semiconductor encapsulation molding to temporarily protect a lead frame during encapsulation molding by being attached to the back surface of the lead frame (the surface opposite to the surface on which a semiconductor element is mounted) in an encapsulation molding step of forming an encapsulating layer that encapsulates the semiconductor element mounted on a die pad of the lead frame.

The support film 1 may be, for example, a film of at least one polymer selected from the group consisting of polyimide, polyamide, polyamideimide, polysulfone, polyethersulfone, polyphenylene sulfide, polyether ketone, polyarylate, polyether ether ketone, and polyethylene naphthalate, or may preferably be a film of polyimide. The polyimide may be an aromatic polyimide. The support film 1 may be a film of copper, aluminum, stainless steel or nickel. In a case where the support film 1 is a film of polymer, the surface thereof may be treated by methods such as chemical treatments such as alkali treatment and silane coupling treatment, physical treatments such as sand mat treatment, plasma treatment, and corona treatment.

The thickness of the support film 1, for example, may be 5 μm or more or may be 100 μm or less or 50 μm or less. The ratio T2/T1 of the thickness T2 of the adhesive layer 2 to the thickness T1 of the support film 1 may be 0.1 or more or may be 0.5 or less, 0.3 or less, or 0.2 or less.

The adhesive layer 2 contains a polymer (hereinafter also referred to as “acrylic polymer”) that contains an alkyl (meth)acrylate, (meth)acryloylmorpholine, and a monomer having a crosslinking group (hereinafter also referred to as “crosslinking monomer”) as monomer units.

The alkyl group in the alkyl (meth)acrylate (the alkyl group moiety other than the (meth)acryloyl group) may be linear or branched. The alkyl group may have 2 or more or 3 or more carbon atoms, may have 30 or less, 20 or less, 10 or less, 7 or less, 5 or less, or 4 or less carbon atoms, or may have 2 or 4 carbon atoms.

Examples of the alkyl (meth)acrylate include methyl (meth)acrylate, ethyl (meth)acrylate, propyl (meth)acrylate, butyl (meth)acrylate, pentyl (meth)acrylate, n-hexyl (meth)acrylate, n-heptyl (meth)acrylate, n-octyl (meth)acrylate, 2-ethylhexyl (meth)acrylate, nonyl (meth)acrylate, and decyl (meth)acrylate.

The crosslinking monomer has a polymerizable group that is copolymerizable with the alkyl (meth)acrylate and (meth)acryloylmorpholine in addition to the crosslinking group. The polymerizable group may be, for example, an ethylenically unsaturated group. The crosslinking group may be, for example, an acidic group. The acidic group may be, for example, a carboxyl group or a sulfo group, and is preferably a carboxyl group.

Examples of the crosslinking monomer having a carboxyl group include (meth)acrylic acid, carboxyethyl (meth)acrylate, carboxypentyl (meth)acrylate, monohydroxyethyl phthalate acrylate, and 2-acryloyloxyethyl succinate.

The acrylic polymer may further contain a monomer other than the alkyl (meth)acrylate, (meth)acryloylmorpholine, and crosslinking monomer as a monomer unit. The other monomer may be, for example, a monomer having a polymerizable group (for example, an ethylenically unsaturated group) and a hydroxyl group. Examples of this monomer include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, and 12-hydroxylauryl (meth)acrylate; and hydroxyalkyl cycloalkane (meth)acrylates such as (4-hydroxymethylcyclohexyl)methyl (meth)acrylate.

In the acrylic polymer, the content of (meth)acryloylmorpholine is 7% by mass or more based on the total amount of the monomer units of the acrylic polymer. This provides a temporary protective film that has excellent adhesive strength at room temperature and can be prevented from remaining on the adherend when peeled off. The content of (meth)acryloylmorpholine preferably may be 7.5% by mass or more, 8% by mass or more, 8.5% by mass or more, or 9.0% by mass or more or may be 20% by mass or less, 18% by mass or less, 17% by mass or less, 16.5% by mass or less, or 16% by mass or less, based on the total amount of the monomer units of the acrylic polymer.

The content of alkyl (meth)acrylate may be 70% by mass or more, 75% by mass or more, or 80% by mass or more or may be 92% by mass or less, 90% by mass or less, or 88% by mass or less, based on the total amount of the monomer units of the acrylic polymer.

The content of the crosslinking monomer may be 1% by mass or more, 2% by mass or more, or 3% by mass or more or may be 10% by mass or less, 6% by mass or less, or 4% by mass or less, based on the total amount of the monomer units of the acrylic polymer.

The content of the other monomer may be 0.1% by mass or more, 0.5% by mass or more, or 1% by mass or more or may be 5% by mass or less, 4% by mass or less, or 3% by mass or less, based on the total amount of the monomer units of the acrylic polymer.

The mass ratio ((meth)acryloylmorpholine/alkyl (meth)acrylate) of the content of (meth)acryloylmorpholine to the content of alkyl (meth)acrylate may be 0.08/1 or more, 0.09/1 or more, or 0.1/1 or more or may be 0.3/1 or less, 0.25/1 or less, 0.23/1 or less, 0.21/1 or less, or 0.2/1 or less.

The acid value of the acrylic polymer may be 10 mgKOH/g or more or 20 mgKOH/g or more or may be 40 mgKOH/g or less or 30 mgKOH/g or less. The hydroxyl value of the acrylic polymer may be 1 mgKOH/g or more or 2 mgKOH/g or more or may be 10 mgKOH/g or less or 5 mgKOH/g or less. The acid value and hydroxyl value of the acrylic polymer are measured in conformity with the methods described in JIS K0070.

The content of the acrylic polymer may be 80% by mass or more, 85% by mass or more, or 90% by mass or more or may be 99.5% by mass or less or 99% by mass or less, based on the total amount of the adhesive layer 2.

The adhesive layer 2 further contains a crosslinking agent. The crosslinking agent is a crosslinking agent capable of crosslinking with the crosslinking group in the acrylic polymer. As such a crosslinking agent, a known crosslinking agent can be used. In a case where the crosslinking group in the acrylic polymer is an acidic group, the crosslinking agent preferably has an epoxy group. The number of epoxy groups in the crosslinking agent may be 2 or more or 3 or more, may be 4 or less, or may be 4.

In an embodiment, the crosslinking agent may be a crosslinking agent having an amino group in addition to an epoxy group. The amino group may be an amino group (a substituted amino group) in which a hydrogen atom in the —NH₂ group is substituted, or may be a tertiary amino group. Such a crosslinking agent may have a group represented by the following Formula (1):

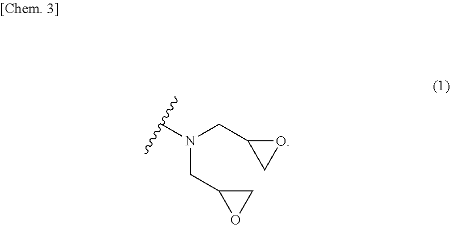 [SMILES: *N(CC1CO1)CC1CO1]

The number of groups represented by the Formula (1) in the crosslinking agent may be 1 or 2.

The crosslinking agent may be a crosslinking agent represented by the following Formula (2):

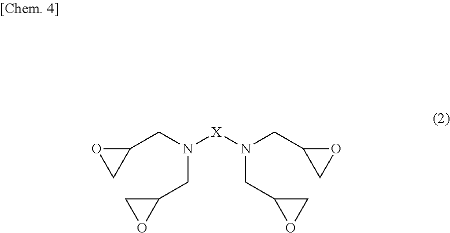

wherein X represents a divalent hydrocarbon group.

The divalent hydrocarbon group represented by X may be a divalent hydrocarbon group having a ring. The ring may be an alicyclic ring or an aromatic ring. The ring may be formed of 5 or more carbon atoms, 8 or less carbon atoms, or 6 carbon atoms. The number of rings in the divalent hydrocarbon group may be 1 or more, may be 3 or less, or may be 1 or 2. In a case where the divalent hydrocarbon group contains a plurality of rings, the plurality of rings may be bonded directly to each other or may be bonded via an alkylene group having 1 to 3 carbon atoms.

The divalent hydrocarbon group represented by X preferably has a cycloalkylene group. The cycloalkylene group may have 5 or more carbon atoms or 8 or less carbon atoms. The cycloalkylene group is preferably a cyclohexylene group.

In an embodiment, the crosslinking agent may be a crosslinking agent that has an ether group in addition to an epoxy group (but does not have an amino group). Such a crosslinking agent may have a group represented by the following Formula (3):

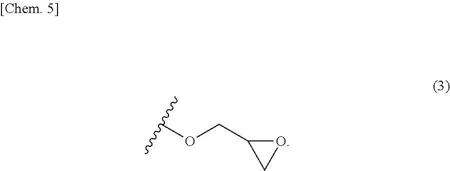 [SMILES: *OCC1CO1]

The number of groups represented by the Formula (3) in the crosslinking agent may be 2 or more or 3 or more, may be 4 or less, or may be 2 or 4.

The crosslinking agent may be a crosslinking agent represented by the following Formula (4):

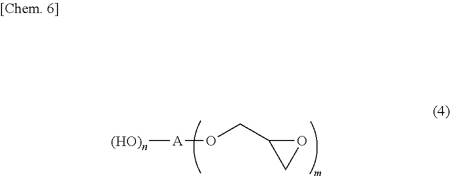

wherein m represents an integer 2 or more, n represents an integer 0 or more, and A represents a residue obtained by eliminating a hydroxyl group from a polyhydric alcohol having a valence of (m+n).

m may be an integer 3 or more, may be an integer 4 or less, or may be 2 or 4. n may be an integer 1 or more, may be an integer 2 or less, or may be 0 or 2. m+n may be an integer 2 or more or may be an integer 6 or less.

The polyhydric alcohol in A may be an aliphatic polyhydric alcohol or a polyhydric alcohol having an ether group. The aliphatic polyhydric alcohol may have 2 or more, 3 or more, or 4 or more carbon atoms, or may have 10 or less, 9 or less, or 8 or less carbon atoms. The polyhydric alcohol having an ether group may be a polyalkylene glycol such as polyethylene glycol.

The crosslinking agent is preferably the above-described crosslinking agent having an epoxy group and an amino group. In this case, it is possible to suppress deterioration of the appearance of the adherend (for example, the generation of unwanted patterns on the adherend) after the temporary protective film is peeled off from the adherend.

The content of the crosslinking agent, based on the total amount of the adhesive layer 2, may be 0.5% by mass or more, may be 15% by mass or less or 10% by mass or less, and is preferably 1% by mass or more, 2% by mass or more, or 2.5% by mass or more, from the viewpoint of suppressing deterioration of the appearance of the adherend after the temporary protective film is peeled off from the adherend.

The content of the crosslinking agent, with respect to 100 parts by mass of the content of acrylic polymer, may be 0.5 parts by mass or more, may be 15 parts by mass or less or 10 parts by mass or less, and is preferably 1 part by mass or more, 2 parts by mass or more, or 3 parts by mass or more, from the viewpoint of suppressing deterioration of the appearance of the adherend after the temporary protective film is peeled off from the adherend.

The adhesive layer 2 may further contain an additional component other than the acrylic polymer and crosslinking agent.

Examples of the additional component contain a polymer other than the acrylic polymer and a coupling agent.

The thickness of the adhesive layer 2 may be 1 μm or more, 2 μm or more, 3 μm or more, 4 μm or more, or 5 μm or more, or may be 20 μm or less, 18 μm or less, 16 μm or less, 14 μm or less, 12 μm or less, or 10 μm or less.

In another embodiment, the temporary protective film may further contain a cover film that is provided on the surface of the adhesive layer opposite to the support film. In other words, the temporary protective film may contain a support film, an adhesive layer, and a cover film in this order. The cover film may be a polyethylene terephthalate film. The thickness of the cover film may be 10 μm or more or may be 100 μm or less.

In another embodiment, the temporary protective film may further contain a non-adhesive layer provided on the side of the support film opposite to the adhesive layer. The non-adhesive layer may be a resin layer that substantially does not exhibit adhesive properties to an adherend at 0 to 270° C. The non-adhesive layer may contain a thermoplastic resin, a thermosetting resin (cured product), or a resin that is a combination thereof. The non-adhesive layer may further contain a filler (for example, ceramic powder, glass powder, silver powder, copper powder, resin particles, or rubber particles), a coupling agent, and the like. The thickness of the non-adhesive layer may be 1 μm or more or may be 10 μm or less.

The temporary protective film can be produced by, for example, a method including a step of applying a varnish containing an acrylic polymer and a crosslinking agent onto a support film and removing the solvent from the coating film to form an adhesive layer.

Next, a method for producing a semiconductor device using the above-described temporary protective film will be described. A method for producing a semiconductor device according to an embodiment includes a step S1 of attaching a temporary protective film to one surface side of a substrate; a step S2 of mounting a semiconductor element on a surface of the substrate opposite to the temporary protective film; a step S3 of encapsulating the semiconductor element; and a step S4 of peeling off the temporary protective film from the substrate in this order. Hereinafter, as an example, a production method for a semiconductor device (semiconductor device package) in a case where the substrate is a lead frame will be described more specifically.

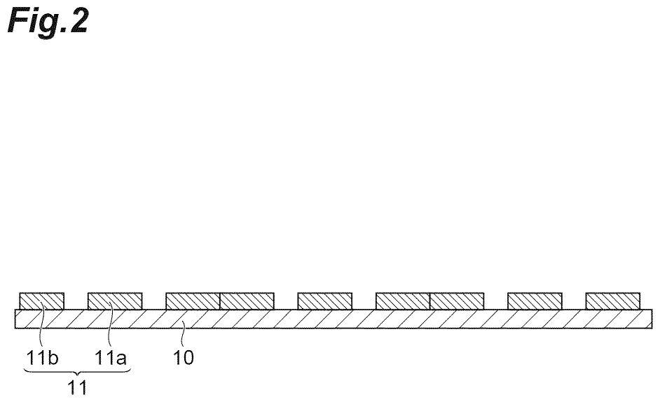

FIG. 2 is a cross-sectional view for explaining an embodiment (step S1) of the production method for a semiconductor device. In step S1, as illustrated in FIG. 2, a temporary protective film 10 is attached to the back surface that is one surface of a lead frame 11 having a die pad 11a and an inner lead 11b. The temporary protective film 10 is attached in such a direction that the adhesive layer of the temporary protective film 10 is in contact with the lead frame 11.

The lead frame 11 may be formed of, for example, an iron-based alloy such as Alloy 42, copper, or a copper-based alloy. The lead frame 11 may have a molded body formed of copper or a copper-based alloy, and a covering layer of palladium, gold, silver, or the like that covers the surface of the molded body.

The temporary protective film 10 is excellent in adhesive strength at room temperature (for example, 25° C.), and therefore can be attached to the lead frame 11 at room temperature. The temporary protective film 10 may be attached to the lead frame 11 while performing heating and pressurization. In this case, the heating temperature may be 150° C. or more or may be 400° C. or less. The pressure may be 0.5 MPa or more or may be 30 MPa or less. The time for heating and pressurization may be 1 second or more or may be 60 seconds or less.

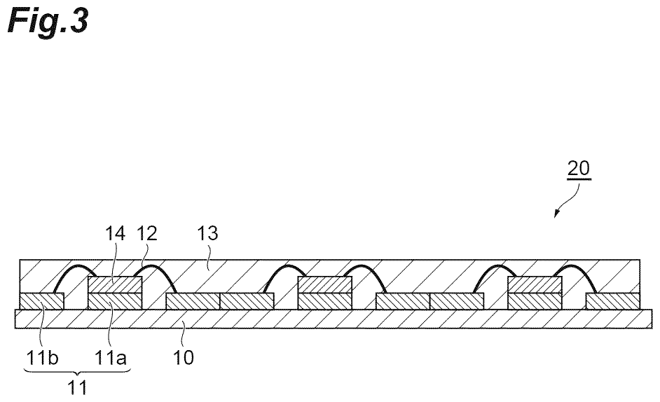

FIG. 3 is a cross-sectional view for explaining an embodiment (step S2 and step S3) of the production method for a semiconductor device. In step S2, as illustrated in FIG. 3, a semiconductor element 14 is mounted on the surface of the die pad 11a opposite to the temporary protective film 10. The semiconductor element 14 is pasted to the die pad 11a via an adhesive (for example, silver paste). After the semiconductor element 14 is pasted to the die pad 11a, reflow connection (Cu Clip connection or the like) may be performed at a maximum temperature of 250 to 440° C. or 250 to 400° C. for 1 to 30 minutes.

Next, the semiconductor element 14 is connected to the inner lead 11b using a wire 12. The wire 12 may be, for example, a gold wire, a copper wire, or a palladium-coated copper wire. The wire 12 may be joined to the semiconductor element 14 and the inner lead 11b, for example, using ultrasonic waves and pushing pressure while performing heating at 200 to 350° C.

Next, in step S3, as illustrated in FIG. 3, an encapsulating layer 13 that encapsulates the semiconductor element 14 and the wire 12 is formed. Thus, a temporarily protected encapsulation molding product 20 having the lead frame 11, the semiconductor element 14, and the encapsulating layer 13 is obtained.

The encapsulating layer 13 is formed by encapsulation molding using an encapsulant. By the encapsulation molding, an encapsulation molding product 20 having a plurality of semiconductor elements 14 and the encapsulating layer 13 that encapsulates the plurality of semiconductor elements 14 collectively may be obtained. During the encapsulation molding, the encapsulant is prevented from spreading to the back surface side of the lead frame 11 as the temporary protective film 10 is provided.

The temperature during the formation of the encapsulating layer 13 (the temperature of the encapsulant) may be 140 to 200° C. or 160 to 180° C. The pressure during the formation of the encapsulating layer may be 6 to 15 MPa or 7 to 10 MPa. The time for encapsulation molding may be 1 to 5 minutes or 2 to 3 minutes.

The encapsulant may contain, for example, an epoxy resin such as a cresol novolac epoxy resin, a phenol novolac epoxy resin, a biphenyl diepoxy resin, or a naphthol novolac epoxy resin. The encapsulant may contain a filler, a flame retardant material such as a bromine compound, a wax component, and the like.

After the formation (encapsulation molding) of the encapsulating layer 13, the temporary protective film 10 is peeled off from the lead frame 11 and the encapsulating layer 13 of the obtained encapsulation molding product 20. In a case where the encapsulating layer 13 is cured, the temporary protective film 10 may be peeled off at any time point corresponding to before or after curing of the encapsulating layer 13.

The temperature at which the temporary protective film 10 is peeled off is not particularly limited, but may be room temperature (for example, 5 to 35° C.). This temperature may be equal to or higher than the glass transition temperature of the adhesive layer. In this case, the peeling properties of the temporary protective film 10 from the lead frame 11 and the encapsulant are far more favorable. When the Tg of the acrylic polymer in the adhesive layer is, for example, 5° C. or less or 0° C. or less, the Tg of the adhesive layer is equal to or lower than room temperature, and favorable peeling properties at room temperature are likely to be obtained.

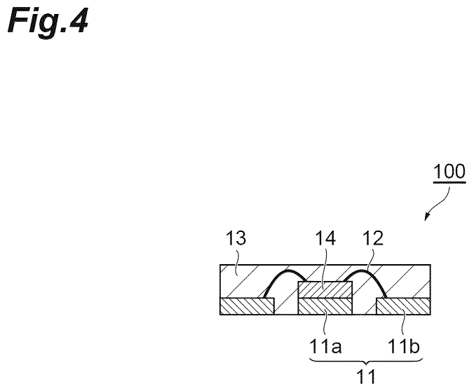

In a case where the lead frame 11 contains a plurality of patterns having the die pads 11a and inner leads 11b, if necessary, the encapsulation molding product 20 can be divided to obtain a plurality of semiconductor devices (semiconductor packages) 100 illustrated in FIG. 4, each having one semiconductor element. In other words, in a case where the lead frame 11 has a plurality of die pads 11a and the semiconductor element 14 is mounted on each of the plurality of die pads 11a, the production method according to an embodiment may further include a step of dividing the encapsulation molding product 20 after the temporary protective film 10 is peeled off from the encapsulation molding product 20 to obtain a semiconductor device (semiconductor package) 100 having one die pad 11a and one semiconductor element 14.

The temporary protective film may be long and therefore used in the form of a reel body wound around a core. In this case, the temporary protective film is attached to the adherend while being unwound from the reel body.

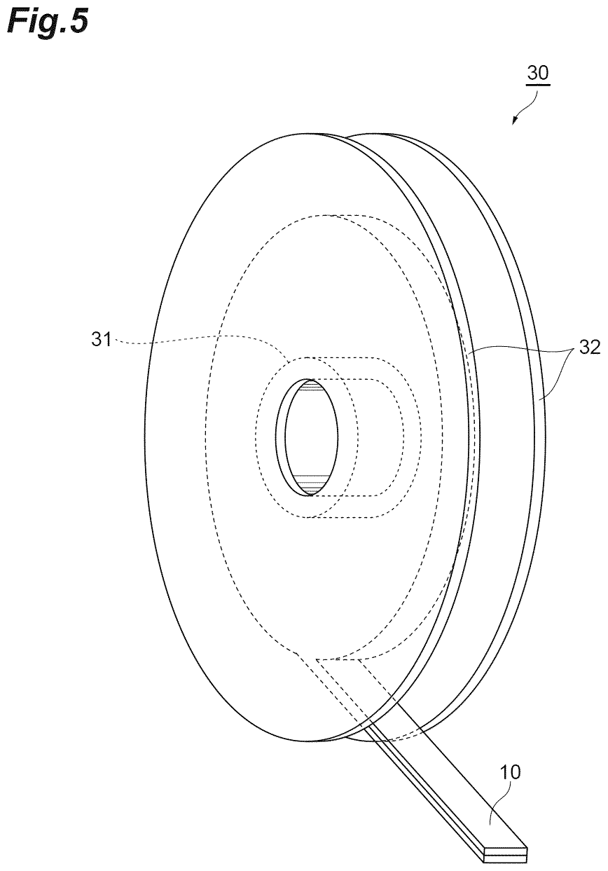

FIG. 5 is a perspective view illustrating an embodiment of a reel body. As illustrated in FIG. 5, a reel body 30 according to an embodiment contains a core 31, the temporary protective film 10 wound around the core 31, and a side plate 32. The width (length in the direction perpendicular to the winding direction) of the core 31 and the temporary protective film 10 may be 1 mm or more, 5 mm or more, or 10 mm or more or may be 1000 mm or less, 800 mm or less, or 500 mm or less. In another embodiment, the reel body may not contain a side plate.

### EXAMPLES

Hereinafter, the present invention will be described more specifically with reference to Examples. However, the present invention is not limited to Examples.

### Example 1

An acrylic polymer A-1 containing butyl acrylate (BA) at 80% by mass, acryloylmorpholine (ACMO) at 16% by mass, acrylic acid at 3% by mass, and another monomer (a monomer having a hydroxyl group) at 1% by mass as monomer units was prepared. In cyclohexanone, 100 parts by mass of acrylic polymer A-1 and 10 parts by mass of crosslinking agent B-1 represented by the following Formula (B-1) were dissolved to obtain a varnish for adhesive layer formation.

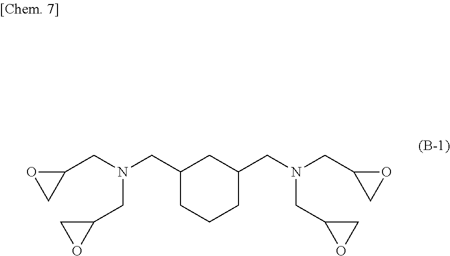

As a support film, a polyimide film (thickness: 25 μm, manufactured by DU PONT-TORAY CO., LTD., trade name: Kapton 100EN) was prepared. The obtained varnish was applied onto one surface of the support film. The coating film on the support film was dried through heating at 90° C. for 1.5 minutes and at 260° C. for 1.5 minutes to form an adhesive layer having a thickness of 5 μm. A temporary protective film was thus obtained.

### Example 2

A temporary protective film was obtained in the same manner as in Example 1, except that an acrylic polymer A-2 obtained by changing the content of BA to 86.5% by mass and the content of ACMO to 9.5% by mass in the monomer composition of acrylic polymer A-1 was used instead of the acrylic polymer A-1.

### Comparative Example 1

A temporary protective film was obtained in the same manner as in Example 1, except that an acrylic polymer A-3 obtained by changing the content of BA to 90.5% by mass and the content of ACMO to 5.5% by mass in the monomer composition of acrylic polymer A-1 was used instead of the acrylic polymer A-1.

### Example 3

A temporary protective film was obtained in the same manner as in Example 1, except that a crosslinking agent B-2 represented by the following Formula (B-2) was used instead of the crosslinking agent B-1.

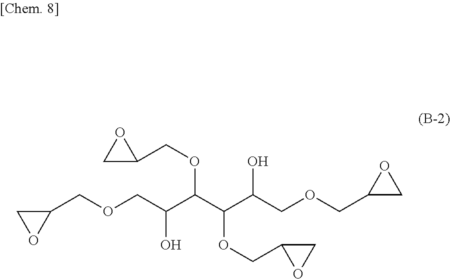 [SMILES: OC(COCC1CO1)C(OCC1CO1)C(OCC1CO1)C(O)COCC1CO1]

### Example 4

A temporary protective film was obtained in the same manner as in Example 1, except that a crosslinking agent B-3 represented by the following Formula (B-3) was used instead of the crosslinking agent B-1.

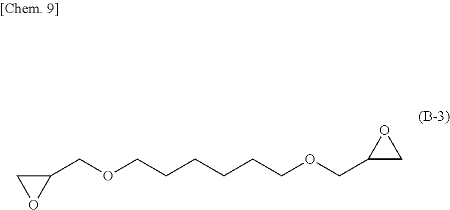 [SMILES: C(CCCOCC1CO1)CCOCC1CO1]

### Examples 5 to 8

Temporary protective films were obtained in the same manner as in Example 1, except that the blending ratio (parts by mass) of the acrylic polymer A-1 to the crosslinking agent B-1 was changed as shown in Table 1.

### Example 9

A temporary protective film was obtained in the same manner as in Example 1, except that the thickness of the adhesive layer was changed to 10 μm.

### (Evaluation of Adhesive Strength)

### (1) After Attachment at Room Temperature

As adherends, an EFTEC64TCu plate (Cu—Fe—P alloy, manufactured by SHINKO ELECTRIC INDUSTRIES CO., LTD.) and a CDA194 palladium-plated plate (PPF, manufactured by SHINKO ELECTRIC INDUSTRIES CO., LTD.) were prepared. Each of the temporary protective films cut to a size of 10 mm×50 mm was attached to each of these adherends in such a direction that the adhesive layer was in contact with the adherend using a hand roller at 25° C. and a load of 20 N to obtain each attached body. Next, using a force gauge, each temporary protective film was peeled off at 25° C. in a direction to be 90 degrees with respect to the main surface of the lead frame at a speed of 50 mm/min. The maximum value (N/m) of the load per 10 mm width of the adhesive layer at that time was measured as the adhesive strength (90 degree peel strength) after attachment at room temperature. The results are shown in Table 1.

(2) Adhesive Strength after Heat Treatment

Each attached body obtained in the same manner as in (1) above was subjected to a heat treatment in an oven in an air atmosphere at 180° C. for 60 minutes and then at 200° C. for 60 minutes. Thereafter, using a force gauge, the temporary protective film was peeled off at 25° C. in a direction to be 90 degrees with respect to the main surface of the lead frame at a speed of 50 mm/min. The maximum value (N/m) of the load per 10 mm width of the adhesive layer at that time was measured as the adhesive strength (90 degree peel strength) after heat treatment. The results are shown in Table 1.

### (3) Evaluation of Residue

Each temporary protective film was attached to a CDA194 palladium-plated Cu plate (lead frame, manufactured by SHINKO ELECTRIC INDUSTRIES CO., LTD.)) in such a direction that the adhesive layer was in contact with the lead frame at 25° C. and a load of 20 N. The obtained attached body was heated in an oven in an air atmosphere at 180° C. for 60 minutes and then at 200° C. for 60 minutes while changing the conditions in this order. The surface of the lead frame opposite to the temporary protective film was subjected to plasma treatment in an argon gas atmosphere (flow rate: 20 sccm) at 150 W for 15 seconds.

Using a mold molding machine (manufactured by APIC YAMADA CORPORATION), an encapsulating layer was formed on the surface of the lead frame opposite to the temporary protective film with an encapsulant (trade name: GE-300, manufactured by Resonac Corporation). The encapsulation conditions were set to 175° C., 6.8 MPa, and 2 minutes. Thereafter, each temporary protective film was peeled off at a speed of 50 mm/min in a direction to be 180° with respect to the surface of the lead frame at 25° C. The state of the adhesive layer remaining on the encapsulating layer after the temporary protective film was peeled off was examined. The proportion of the area occupied by the residue of the adhesive layer to the area of the surface of the encapsulating layer was determined. Based on the proportion of the area occupied by the residue of the adhesive layer, the peeling properties after encapsulation molding were evaluated according to the following five-level criteria. The results are shown in Table 1.

5: 60% to 100%

4: 40% or more and less than 60%

3: 20% or more and less than 40%

2: 10% or more and less than 20%

1: 0% or more and less than 10%

### (4) Evaluation of Appearance

For the encapsulating layer after each temporary protective film was peeled off in (3) above, it was examined whether or not there was a portion having a different hue on the encapsulating layer. Based on whether or not there was a portion having a different hue, the appearance after encapsulation molding was evaluated according to the following criteria. The results are shown in Table 1.

A: There is no portion having a different hue (almost uniformly black (the color of the encapsulating layer))

B: There are portions having a different hue (there are some white linear regions on the black surface)

TABLE 1

| | | | Example | Example | Comparative | Example | Example |
|---|---|---|---|---|---|---|---|
| | | | 1 | 2 | Example 1 | 3 | 4 |
| Blending ratio | Acrylic | A-1 | 100 | — | — | 100 | 100 |
| (parts by mass) | polymer | A-2 | — | 100 | — | — | — |
| | | A-3 | — | — | 100 | — | — |
| | Crosslinking | B-1 | 10 | 10 | 10 | — | — |
| | agent | B-2 | — | — | — | 10 | — |
| | | B-3 | — | — | — | — | 10 |
| Thickness of adhesive layer (μm) | | | 5 | 5 | 5 | 5 | 5 |
| Evaluation | Adhesive | Cu | 21 | 22 | 10 | 29 | 44 |
| results | strength after | | | | | | |
| | attachment | | | | | | |
| | at room | PPF | 28 | 25 | 16 | 40 | 53 |
| | temperature | | | | | | |
| | (N/m) | | | | | | |
| | Adhesive | Cu | 44 | 48 | 30 | 38 | 70 |
| | strength after | | | | | | |
| | heat | | | | | | |
| | treatment | PPF | 63 | 74 | 41 | 35 | 78 |
| | (N/m) | | | | | | |

| | | | | | |
|---|---|---|---|---|---|
| Residue | 1 | 1 | 3 | 1 | 1 |
| Appearance | A | A | A | B | B |

| | | | Example | Example | Example | Example | Example |
|---|---|---|---|---|---|---|---|
| | | | 5 | 6 | 7 | 8 | 9 |
| Blending ratio | Acrylic | A-1 | 100 | 100 | 100 | 100 | 100 |
| (parts by mass) | polymer | A-2 | — | — | — | — | — |
| | | A-3 | — | — | — | — | — |
| | Crosslinking | B-1 | 7 | 5 | 3 | 0.71 | 10 |
| | agent | B-2 | — | — | — | — | — |
| | | B-3 | — | — | — | — | — |
| Thickness of adhesive layer (μm) | | | 5 | 5 | 5 | 5 | 10 |
| Evaluation | Adhesive | Cu | 20 | 20 | 35 | 60 | 36 |
| results | strength after | | | | | | |
| | attachment | | | | | | |
| | at room | PPF | 26 | 28 | 26 | 75 | 42 |
| | temperature | | | | | | |
| | (N/m) | | | | | | |
| | Adhesive | Cu | 45 | 50 | 50 | 90 | 98 |
| | strength after | | | | | | |
| | heat | | | | | | |
| | treatment | PPF | 50 | 53 | 60 | 93 | 85 |
| | (N/m) | | | | | | |

| | | | | | |
|---|---|---|---|---|---|
| Residue | 1 | 1 | 1 | 1 | 1 |
| Appearance | A | A | A | B | A |

### REFERENCE SIGNS LIST

1: support film, 2: adhesive layer, 10: temporary protective film, 11: lead frame, 11a: die pad, 11b: inner lead, 12: wire, 13: encapsulating layer, 14: semiconductor element, 20: encapsulation molding product, 100: semiconductor device.

1. A temporary protective film for production of a semiconductor device, comprising:
a support film; and
an adhesive layer provided on the support film,
wherein the adhesive layer comprises:
a polymer comprising an alkyl (meth)acrylate, (meth)acryloylmorpholine, and a monomer having a crosslinking group, as monomer units; and
a crosslinking agent capable of crosslinking with the crosslinking group, and
wherein a content of the (meth)acryloylmorpholine is 7% by mass or more based on a total amount of the monomer units of the polymer.

2. The temporary protective film according to claim 1, wherein the crosslinking group is an acidic group and the crosslinking agent has an epoxy group.

3. The temporary protective film according to claim 2, wherein the crosslinking agent further has an amino group.

4. The temporary protective film according to claim 1, wherein the crosslinking agent has a group represented by the following Formula (1):

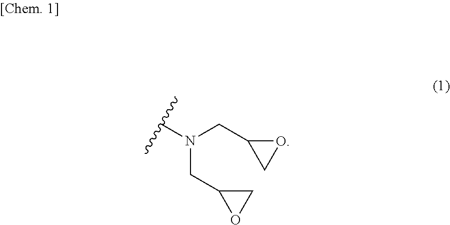 [SMILES: *N(CC1CO1)CC1CO1]

5. A method for producing a semiconductor device, comprising:
attaching a temporary protective film to one surface side of a substrate;
mounting a semiconductor element on a surface of the substrate opposite to the temporary protective film;
encapsulating the semiconductor element; and
peeling off the temporary protective film from the substrate, in this order,
wherein the temporary protective film comprises:
a support film; and
an adhesive layer provided on the support film,
wherein the adhesive layer comprises:
a polymer containing an alkyl (meth)acrylate, (meth)acryloylmorpholine, and a monomer having a crosslinking group, as monomer units; and
a crosslinking agent capable of crosslinking with the crosslinking group, and
wherein a content of the (meth)acryloylmorpholine is 7% by mass or more based on a total amount of the monomer units of the polymer.

6. The method according to claim 5, wherein the crosslinking group is an acidic group and the crosslinking agent has an epoxy group.

7. The method according to claim 6, wherein the crosslinking agent further has an amino group.

8. The method according to claim 5, wherein the crosslinking agent has a group represented by the following Formula (1): 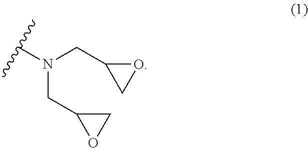 [SMILES: *N(CC1CO1)CC1CO1]
